(19) United States
(12) Patent Application Publication
(10) Pub. No.: US 2008/0017916 A1
(43) Pub. Date: Jan. 24, 2008

(54) Semiconductor device and method of manufacturing the same

(76) Inventor: Hidemi Kanetaka, Yokkaichi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/822,661

(22) Filed: Jul. 9, 2007

(30) Foreign Application Priority Data
Jul. 10, 2006 (JP) 2006-189304

(51) Int. Cl. H01L 29/788; H01L 21/336

(52) U.S. Cl. 257/316; 438/261; 257/E29.3; 257/E21.422

(57) ABSTRACT

A semiconductor device including a plurality of element isolation insulating films filling a trench defined in a semiconductor substrate and having an upper end that upwardly projects from a substrate surface, a width of the upper end being narrower than a width at a height of the substrate surface; and a first gate electrode composed of a lower electrode having an upper surface at level with a height of the upper end of the element isolation insulating film and having a sidewall surface in alignment with a sidewall surface of the plurality of element isolation insulating films projecting from the substrate surface and an upper electrode formed on the upper surface of the lower electrode and having a width narrower than a width of the lower electrode, the upper electrode having a sidewall surface which is not in alignment with the sidewall surface of the element isolation insulating film.

### CROSS-REFERENCE TO RELATED APPLICATIONS

This application is based upon and claims the benefit of priority from the prior Japanese Patent Application No. 2006-189304, filed on, Jul. 10, 2006 the entire contents of which are incorporated herein by reference.

### FIELD

The present disclosure is directed to a semiconductor device having a stacked gate structure and a method of manufacturing the same.

### BACKGROUND

A non-volatile semiconductor device provided with a memory cell transistor having a stacked gate structure, for example, is disclosed in patent publication JP 2004-22819A. The memory cell transistor disclosed in the publication employs a structure in which the surface defined by the inter-electrode insulating film formed on the upper side-surface of the floating gate electrode is not in alignment with the side of the element isolation insulating film(refer to paragraph 0007 for example, and FIGS. 13 to 14). That is, the lower layer polycrystalline silicon layer is formed as an underlying structure of the inter-gate electrode insulating film formed on the upper side surface of the floating gate electrode. The side surface of the lower layer floating gate electrode is formed vertically relative to the semiconductor substrate and in alignment with the side surface of the element isolation insulating film.

Processing of the gate electrode for separating the gate electrodes are carried out along the word-line direction by RIE (Reactive Ion Etching). Due to growing demand for further integration of device elements, it is becoming increasingly difficult to configure the conditions for gate electrode processing. The structure disclosed in JP 2004-22819 A does not suffer any digging of the substrate even if prolonged etch is carried out under high selectivity relative to polycrystalline silicon if limited to the surface where the inter-electrode insulating film is formed on the side surface of the floating gate electrode.

However, in case the inter-electrode insulating film is sufficiently etched to the extent to be removed by RIE process in the structure disclosed in the above publication, the element isolation insulating film positioned on the side surface of the lower layer floating gate electrode gets removed. In case the height of the element isolation insulating film from the semiconductor substrate surface is excessively lowered by removal of the element isolation insulating film, the effect of removal of the floating gate electrode performed thereafter may reach the inner portion of the semiconductor substrate along the interface with the element isolation insulating film. The effect of the etch process reaching the inner portion of the semiconductor device leads to defective impact on the device.

On the other hand, when etch amount of the inter-electrode insulating film is insufficient, material constituting the floating gate electrode remains in a portion where the gate electrodes are separated, more specifically, on the sidewall surface of the element isolation insulating film, which leads to shorting of neighboring floating gate electrodes in the predetermined direction.

### SUMMARY

The present disclosure provides a semiconductor device with improved reliability and the method of manufacturing such semiconductor device.

In one aspect of the present disclosure, a semiconductor device includes a semiconductor substrate; a plurality of element isolation insulating films delimiting the semiconductor substrate into a plurality of element forming regions, each element isolation insulating film formed so as to fill a trench defined in the semiconductor substrate and having an upper end that upwardly projects from a surface of the semiconductor substrate, and a width of the upper end being formed narrower than a width at a height of a surface portion of the semiconductor substrate; a first gate electrode formed on the element forming region via a first gate insulating film, the first gate electrode having a lower electrode having an upper surface portion at level with a height of the upper end of the element isolation insulating film and having a sidewall surface in alignment with a sidewall surface of the element isolation insulating film projecting from the surface of the semiconductor substrate, the lower electrode being formed between the plurality of element isolation insulating films; and having an upper electrode formed on the upper surface portion of the lower electrode and having a width narrower than a width of the lower electrode, the upper electrode having a sidewall surface which is not in alignment with the sidewall surface of the element isolation insulating film; a second gate insulating film formed so as to cover the upper S surface of the lower electrode of the first gate electrode, an upper surface of the element isolation insulating film, and a surface of the upper electrode of the first gate electrode; and a second gate electrode formed on the second gate insulating film.

In another aspect of the present disclosure, a semiconductor device includes a semiconductor substrate including a first upper surface having an element forming region and an element isolation region, the element isolation region having a trench; an element isolation insulating film embedded in the trench, the element isolation insulating film including a protruding portion protruding from the first upper surface of the semiconductor substrate and a surface level portion located at an upper end portion of the trench, the protruding portion including a first side surface and a second upper surface having a first width, the surface level portion including a second width being longer than the first width; a floating gate electrode having an underside formed on the semiconductor substrate in the element forming region via a first gate insulating film, the floating gate electrode including a lower portion and an upper portion formed on the lower portion, the lower portion including a third upper surface being flush with the second upper surface of the element isolation insulating film and a second side surface contacting with the first side surface of the element isolation insulating film, the third upper surface including a third width, the upper portion including a third side surface and a fourth upper surface having a fourth width being shorter than the third width of the third upper surface; a second gate insulating film formed on the second, the third and the fourth upper surfaces and the third side surface; and a control gate electrode formed on the second gate insulating film.

In another aspect of the present disclosure, a method of manufacturing a semiconductor device includes forming a first insulating film on a semiconductor substrate; forming a plurality of element isolation insulating films separating a surface of the semiconductor substrate in a predetermined gate-width direction while projecting an upper end thereof upward relative to an upper surface of the first insulating film; processing each of the element isolation insulating film so that a width in the predetermined gate-width direction of the upper end of the element isolation insulating film is narrower than a width in the predetermined gate-width direction of the element isolation insulating film at a height of a surface portion of the semiconductor substrate; forming a first conductive film on a first gate insulating film formed on the surface of the semiconductor substrate so as to fill gaps between the plurality of element isolation insulating films; forming a second conductive film on the first conductive film so that a sidewall surface in the gate width direction is not in alignment with a sidewall surface of the element isolation insulating film in an upper side of the semiconductor substrate; forming the second gate insulating film so as to cover the second conductive film; forming a third conductive film on the second gate insulating film; and separating the third conductive film, the second gate insulating film, the second conductive film, and the first conductive film into a plurality of portions in a direction intersecting the gate-width direction by removing the third conductive film, the second gate insulating film, the second conductive film and the first conductive film along the predetermined gate-width direction within the surface of the semiconductor substrate.

Yet, in another aspect of the present disclosure, a method of manufacturing a semiconductor device includes forming a first silicon oxide film on a semiconductor substrate; forming a silicon nitride film on the first silicon oxide film; forming a second silicon oxide film on the silicon nitride film; coating a first resist on the second silicon oxide film, and patterning the first resist into a predetermined pattern; etching the second silicon oxide film by using the patterned first resist as a mask, and etching the silicon nitride film, the first silicon oxide film, and the semiconductor substrate by using the etched second silicon oxide film as a mask, and forming a plurality of trenches in a first direction; filling the trench with a third silicon oxide film; planarizing the second silicon oxide film and the third silicon oxide film by using the silicon nitride film as a stopper; arranging a width of an upper end of the third silicon oxide film projecting from a surface of the semiconductor substrate to be narrower than a width of the third silicon oxide film at a height of a surface portion of the semiconductor substrate by removing the silicon nitride film exposed by planarization by wet-etch process and removing a portion of a side surface of the third silicon oxide film projecting from the surface of the semiconductor substrate; forming a first gate insulating film on the semiconductor substrate in a portion between a plurality of the third silicon oxide films projecting from the surface of the semiconductor substrate; filling a region delimited by the plurality of the third silicon oxide films projecting from the surface of the semiconductor substrate and overlying the first gate insulating film with a first conductive film, planarizing the first conductive film by using the third silicon oxide film as a stopper; forming a second conductive film on the planarized first conductive film; coating a resist on the second conductive film and patterning the resist by photolithography process, etching the second conductive film by using the patterned resist as a mask, and forming the second conductive film having a width of the sidewall surface narrower than the width of the first conductive film on the first conductive film; forming a second gate insulating film on the first conductive film, the second conductive film, and the third silicon oxide film; forming a third conductive film on the second gate insulating film; and removing the third conductive film, the second gate insulating film, the second conductive film and the first conductive film in a direction intersecting the first direction and separating the third conductive film, the second gate insulating film, the second conductive film, and the first conductive film in the first direction.

### BRIEF DESCRIPTION OF THE DRAWINGS

Other objects, features and advantages of the present disclosure will become clear upon reviewing the following description of the embodiment of the present disclosure with reference to the accompanying drawings, in which,

FIG. 1 illustrates a portion of an electrical configuration of a memory cell region indicating one embodiment of the present disclosure;

FIG. 2 is a schematic plan view illustrating a structure of the memory cell region;

FIG. 3 is a schematic vertical cross-sectional view of a portion of the memory cell region structure taken along line 3-3 of FIG. 2;

FIGS. 4 to 18 are schematic vertical cross-sectional views (part 1 to 15) illustrating a portion of the memory cell region undergoing one manufacturing step; and

FIGS. 19 to 23 are schematic perspective views (part 1 to 5) illustrating a portion of the memory cell region.

### DETAILED DESCRIPTION

One embodiment employing a semiconductor device of the present disclosure to a NAND flash memory device will be described with reference to the drawings.

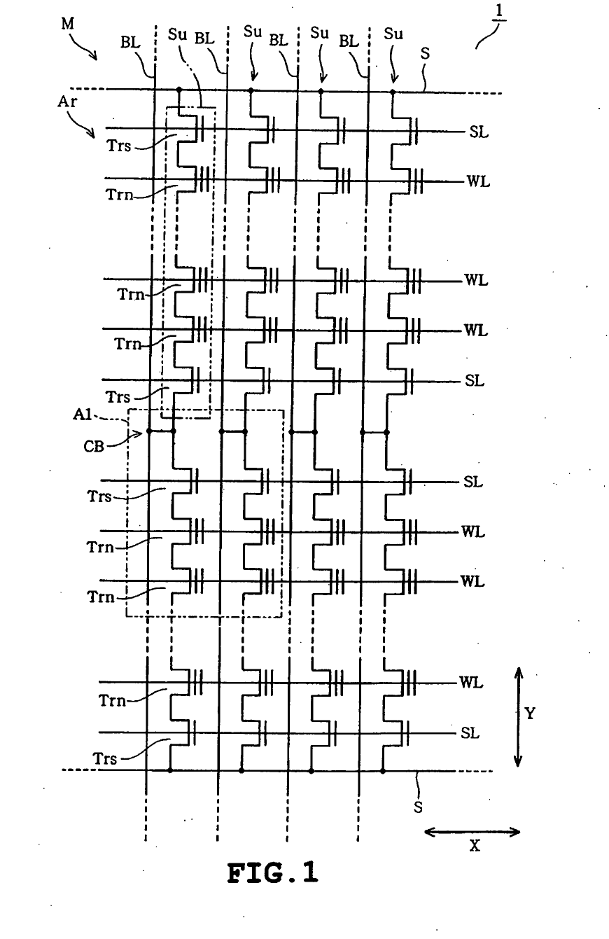

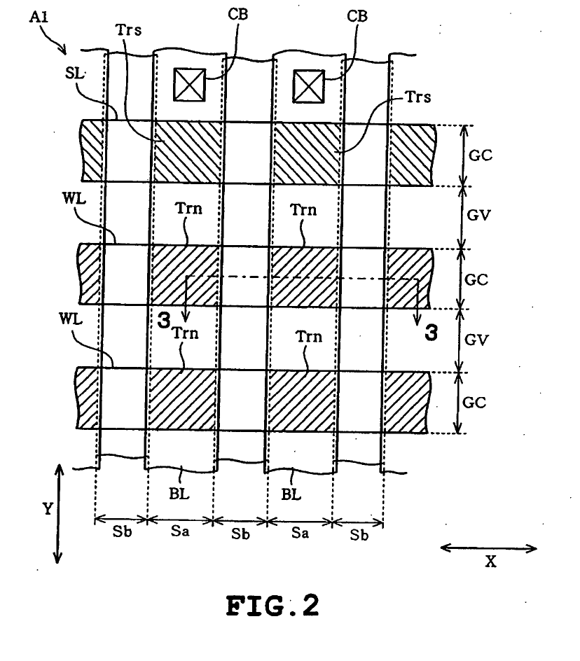

FIG. 1 illustrates an equivalent circuit indicating a portion of a memory cell array configured in the memory cell region of a NAND flash memory. FIG. 2 is a plan view schematically illustrating a structure of a memory cell in region Al of FIG. 1.

Referring to FIG. 1, matrix of NAND cell units Su are configured in the memory cell array Ar of a NAND flash memory device 1 serving as a semiconductor device. The NAND cell unit Su is constituted by two select gate transistors Trs, and a plurality (eight for example: nth power of 2 (n is a positive integer)) of memory cell transistors Trn connected in series to the two select gate transistors Trs. The plurality of neighboring memory cell transistors Trn shares source/drain regions within a single NAND cell unit Su.

Referring to FIG. 1, the memory cell transistors Trn aligned in an X-direction (corresponding to word line direction and gate-width direction) are connected to a common word line (control gate line) WL. Also, the select gate transistors Trs aligned in the X-direction in FIG. 1 are connected to a common select gate line SL. The select gate transistors Trs are connected to a bit line BL extending in the Y-direction (corresponding to a direction intersecting the gate-width direction and the bit-line direction) perpendicularly intersecting the X-direction indicated in FIG. 1 via the bit line contact CB.

A plurality of NAND cell units Su are separated from one another by an element isolation region Sb taking an STI (Shallow Isolation Trench) structure. The memory cell transistors Trn are formed at portions intersecting the word line WL extending in the Y-direction formed at predetermined intervals in the X-direction.

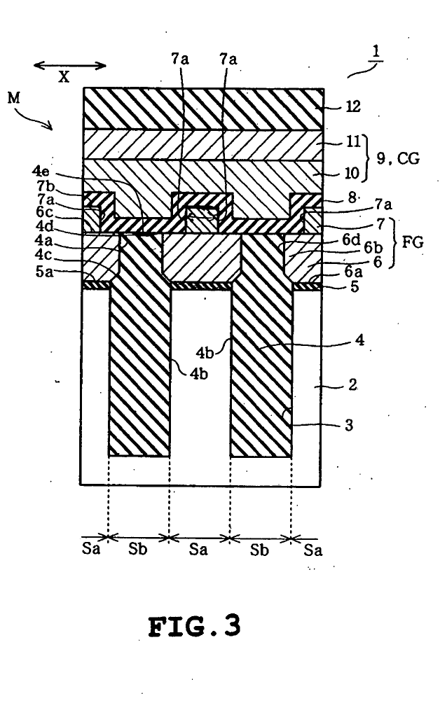

The gate electrode structure employed in a memory cell region M of the flash memory device 1 which constitutes the features of the present disclosure will be described with reference to FIG. 3. FIG. 3 schematically illustrates a cross sectional view taken along line 3-3 of FIG. 2.

The p-type silicon substrate 2 serving as a semiconductor substrate has both the memory cell region M and the peripheral region (not shown) formed thereto. A description will be given hereinafter on the stacked gate electrode structure formed in the memory cell region.

Referring to FIG. 3, the surface layer of the silicon substrate 2 has element isolation trenches 3 formed in a plurality of element isolation regions Sb. The element isolation trenches 3 are filled with an element isolation insulating film 4. The element isolation insulating film 4 electrically isolates the neighboring floating gate electrodes FG and constitutes the element isolation regions Sb taking the so called STI structure.

The element isolation insulating film 4 filling the element isolation trench 3 is formed so that the upper portion thereof upwardly protrudes from the surface of the silicon substrate 2 to define the protruding portion 4a in a tapered form.

The X-directional (word line direction) width of the protruding portion 4a (corresponding to a first width), more specifically, the width of the upper end portion (corresponding to a second upper surface) of the element isolation insulating film 4 is formed so as to be narrower than the X-directional width (corresponding to a second width) of the portion of the element isolation insulating film 4 corresponding to the surface portion (corresponding to a surface level portion) of the silicon substrate 2. The protruding portion 4a may take a single-peaked form, lumped form, trapezoid form, tapered form or a curved form in which the outer surface thereof is curved downward. The protruding portion 4a has a sloped surface (tapered surface or curved surface) sloped relative to the upper surface of the silicon substrate 2 in the surface portion (proximity of the portion where silicon oxide film 5 (later described)) of the silicon substrate 2.

The element isolation insulating film 4 is formed so as to isolate the element forming region Sa (active region) of the silicon substrate 2 into a plurality of portions. The silicon oxide film 5 is formed on the element forming regions Sa of the silicon substrate 2 isolated by the element isolation insulating film 4. The silicon oxide film 5 is composed of a thermal oxide film, and functions as a gate oxide film, a tunnel insulating film, and a first gate insulating film.

A first conductive layer 6 is formed as a lower electrode (corresponding to a lower portion) on the silicon oxide film 5. The first conductive layer 6 is composed of polycrystalline silicon doped with impurities such as phosphorous. An upper surface portion 6c (corresponding to a third upper surface) of the first conductive layer 6 is formed as a planar surface flush with an upper surface portion 4e (corresponding to the second upper surface) of the protruding portion 4a constituting the upper end portion of the element isolation insulating film 4. “Flush” indicates the state of being substantially flush and is inclusive of marginal errors and tolerance that may occur in the actual manufacturing steps.

The first conductive layer 6 is formed so as to interpose a pair of element isolation insulating films 4 upwardly projecting from the surface of the silicon substrate 2 and a sidewall surface 6d (corresponding to a second side surface) of the first conductive layer 6 is in alignment with a sidewall surface 4d (4c) (corresponding to a first side surface) of the element isolation insulating film 4. Since the element isolation insulating film 4 has the protruding portion 4a formed thereto, the first conductive layer 6 having its sidewall surface 6d in alignment with the sidewall 4d (4c) of the element isolation insulating film 4 has an expanding portion 6b which expands upward and in the X-direction from a contacting portion 6a (corresponding to an underside of the floating gate electrode) contacting the silicon oxide film 5 and which protrudes to the element isolation insulating film side.

A second conductive layer 7 serving as an upper electrode (corresponding to an upper portion) is formed on the upper surface portion 6c of the first conductive layer 6. The x-directional width of the second conductive layer 7 (corresponding to a fourth width) defined by sidewall surfaces 7a (corresponding to a third side surface) of the second conductive layer 7 is narrower than the X-directional width defined by sidewall surfaces 4d (refer to the portion indicated by reference symbol 4d in FIG. 3) (corresponding to a third width) of the neighboring element isolation insulating films 4 in the portion corresponding to the height of the upper surface portion 6c of the first conductive layer 6.

Further, the second conductive layer 7 is formed substantially in the X-directional mid-portion on the upper surface portion 6c of the first conductive layer 6.

A contacting portion (corresponding to a first corner portion) between the side surface 7a of the second conductive layer 7 and the upper surface 6c of the first conductive layer 6, and a corner (corresponding to a second corner portion) of the side surface (sidewall surface 6d) and the upper surface 6c of the first conductive layer 6 are distanced in the X-direction by a predetermined spacing.

The second conductive layer 7 is composed of polycrystalline silicon doped with impurities such as phosphorous. The sidewall surface 7a of the second conductive layer 7 is formed on a different plane from the interface (corresponding to the sidewall surface 4d of the protruding portion 4a of the element isolation insulating film 4) of the protruding portion 4a of the element isolation insulating film 4 and the sidewall surface 6d of the first conductive layer 6.

The first and the second conductive layers 6 and 7 function as a floating gate electrode FG (corresponding to the first gate electrode) and the floating gate electrode FG has its X-directional cross section substantially formed in an upside down T-shape. The sidewall surface 7a of the second conductive layer 7 is formed on a plane substantially vertical relative to the upper surface of the silicon substrate.

Also, the X-directional width (corresponding to the fourth width) defined by the confronting sidewall surfaces 7a of the second conductive layer 7 is formed narrower than the X-directional width of the silicon oxide film 5 formed on the silicon substrate 2.

The second gate insulating film 8 is formed so as to cover the upper surface of the first conductive layer 6, the surfaces (the upper surface and the side surfaces) of the second conductive layer 7 and the upper surface of the element isolation insulating film 4. The second gate insulating film 8 is composed of a stacked structure constituted by oxide film layer and nitride film layer such as ONO film (Oxide (Oxide film layer)-Nitride (nitride film layer)-Oxide (oxide film layer)) and NONON film (Nitride-Oxide-Nitride-Oxide-Nitride). The second gate insulating film 8 is formed as inter-conductive layer insulating film situated between the first and the second conductive layers 6 and 7 and a third conductive layer 9 (corresponding to a control gate electrode). The second gate insulating film 8 functions as an inter-gate insulating film that retains predetermined insulativity between the floating gate electrode FG and the control gate CG.

The third conductive layer 9 is formed so as to cover the upper side of the second gate insulating film 8. The third conductive layer 9 is composed of a lower conductive layer 10 and an upper conductive layer 11 formed on the lower conductive layer 10.

The lower conductive layer 10 is composed of polycrystalline silicon doped with impurities such as phosphorous. The upper conductive layer 11 is formed by tungsten silicide, for example, and functions as low-resistive metal containing layer. The third conductive layer 9 functions as the control gate electrode CG (corresponding to the second gate electrode). The control gate electrode CG covers the second gate electrode 7 and is formed over a plurality of element forming regions Sa and the element isolation regions Sb. A silicon nitride film 12 is formed on the control gate electrode layer CG. Though not shown, an interlayer insulating film and bit lines BL are formed over the silicon nitride film 12 to constitute the flash memory device 1. The purpose of providing the protruding portion 4a on the element isolation insulating film 4 is to allow the first conductive layer 6 to be completely etched away without remainder.

When a plurality of control gate electrodes CG and floating gate electrodes FG are formed in the direction to intersect the cross section illustrated in FIG. 3 (Y-direction), a process is required to separate the first to the third conductive layers 6, 7 and 9 in the direction to intersect the cross section illustrated in FIG. 3 (Y-direction). In case the sidewall (sidewall surface) 4d of the element isolation insulating film 4 is formed vertically relative to the upper surface of the silicon substrate 2 in the upper side of the silicon substrate 2, the first conductive layer 6 is prone to remain on the silicon oxide film 5, more specifically, on the sidewall portion 4d of the element isolation insulating film 4 (sidewall interface with the floating gate electrode FG immediately above the silicon substrate 2) when the process to separate the first conductive layers 6 is carried out.

The remainder first conductive layer 6 causes the plurality of floating gate electrodes FG provided in the direction perpendicular to the cross section illustrated in FIG. 3 (Y-direction) to be conducted to one another by the remainder first conductive layer 6. Thus, the element isolation insulating film 4 may be formed in a shape to prevent the first conductive layer 6 from remaining on the above described portion when etching the first conductive layer 6.

In the present embodiment, since the element isolation insulating film 4 is provided with a protruding portion 4a formed in a tapered form from the upper surface side of the silicon substrate 2, the first conductive layer 6 is less prone to remain when separating the first conductive layer 6, thereby maintaining insulativity between the plurality of floating gate electrodes FG. Especially, the protruding portion 4a of the element isolation insulating film 4 is formed as a sloped surface sloped with respect to the upper surface of the silicon substrate 2 so that its upper outer surface 4c projects to the upper side in the proximity of the region where the silicon oxide film 3 is formed. Thus, the first conductive layer 6 attached on the upper outer surface 4c can be reliably removed easier as compared to the first conductive layer 6 on the gate electrode isolation region GV.

Also, when separating each gate electrode (FG and CG) in the Y-direction, the etch condition cannot be selectively set for the second gate insulating film 8 and the element isolation insulating film 4. When the sidewall surface 7a of the second conductive layer 7 is formed flush with the sidewall surface 4d of the protruding portion 4a of the element isolation insulating film 4 and the sidewall surface of the element isolation insulating film 4 is formed vertically relative to the upper surface of the silicon substrate 2, the etch process may proceed into the silicon substrate 2 along the sidewall surface 4b of the element isolation insulating film 4.

Then, in case the etching device is not capable of etch end point detection (detection of etch depth), the etch depth will have to be measured by the etch time.

According to the present embodiment, the sidewall surface 7a of the second conductive layer 7 is formed so as not to be aligned with the sidewall surface 4d of the protruding portion 4a of the element isolation insulating film 4. Thus, the deficiency in which the silicon substrate 2 is etched when etching the second gate insulating film 8 formed on the sidewall surface 7a of the second conductive layer 7 can be prevented, thereby improving device reliability.

Also, since the width between the sidewalls 6d of the first conductive layer 6 is formed to be wider than the width of the contacting portion 6a where the first conductive layer 6 contacts the silicon oxide film 5, and the lower end of the sidewall surface 6d of the first conductive layer 6 contacts the silicon oxide film 3 via the sloped outer surface 4c, the lower end of the sidewall surface 6d does not contact the silicon substrate 2 or the silicon oxide film 3. Thus, even if the element isolation insulating film 4 is etched when etching the second gate insulating film 8, the deficiency in which the silicon substrate 2 is etched can be further prevented, thereby improving the yield rate.

Further, the second conductive layer 7 is formed in the substantial mid-portion of the upper surface portion 6c of the first conductive layer 6 and the x-directional width of the second conductive layer 7 defined by the sidewall surfaces 7a of the second conductive layer 7 is narrower than the X-directional width defined by the sidewall surfaces 4b (refer to the portion indicated by reference symbol 4b in FIG. 3) of the neighboring element isolation insulating films 4 in the portion corresponding to the upper surface portion 6c of the first conductive layer 6. The confronting area of the floating gate electrode FG and the control gate electrode CG can be increased.

One indicator for describing the characteristics of the memory cell constituting the flash memory device 1 is the coupling ratio. The coupling ration Cr is described as:
Cr=Cono/(Cono+Cox) (1)

It is desirable for the coupling ratio Cr of the above equation (1) to take a large value. Cono indicates the capacitance between the floating gate electrode FG and the control gate electrode CG confronting each other over the second gate insulating film 8 interposed therebetween and Cox indicates the capacitance between the silicon substrate 2 and the first conductive layer 6 confronting each other over the silicon oxide film 5. The value of the coupling ratio Cr is proportionate to the confronting area between the control gate electrode CG and the floating gate electrode FG, in which the coupling ratio Cr increases when the confronting area increases and decreases when the confronting area decreases.

Conventionally, a method has been generally employed in which, for example, the floating gate electrode FG is projected over the upper surface of the element isolation region Sb to increase the area between the upper surface of the floating gate electrode FG and the lower surface of the control gate electrode CG to increase the coupling ratio. However, when the floating gate electrode FG is configured to project over the upper surface of the element isolation region Sb to meet the demand for integration of device elements; it becomes increasingly difficult to fill the third conductive layer 9 constituting the control gate electrode CG between the neighboring floating gate electrodes FG. Failure in filling the third conductive layer 9 brings adverse effects in obtaining desired coupling ratio and device characteristics.

In the present embodiment, in order to attain integration of device elements, the second conductive layer 7 having the width between the sidewall surfaces 7a configured to be narrower than the width between the sidewall surfaces 6d of the first conductive layer 6 is provided in the substantial mid-portion of the upper surface portion 6c of the first conductive layer 6 to increase the height of the floating gate electrode FG. Consequently, the confronting area is increased by using the sidewall surfaces of the second conductive layer 7 and the upper surface of the first conductive layer 6, thereby increasing the coupling ratio while achieving integration of device elements.

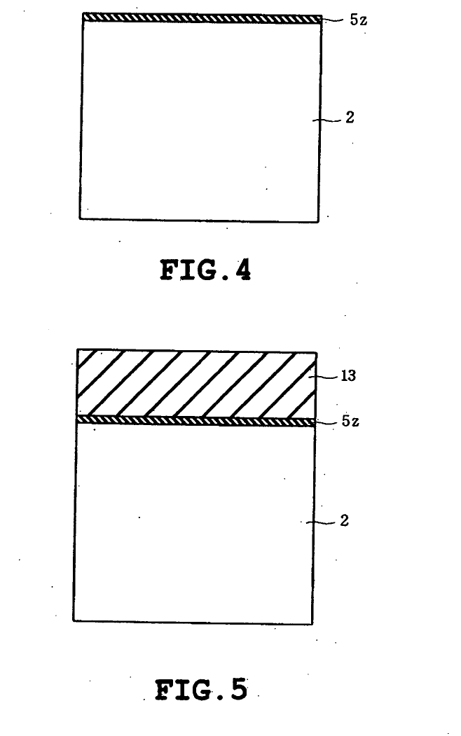

The manufacturing steps of the above described device will be described with reference to FIGS. 4 to 23. The steps described hereinafter may be omitted as required and likewise, well known steps may be added as required.

Referring to FIG. 4, the silicon oxide film 5z is formed by thermally oxidating the upper surface of the silicon substrate 2. The silicon oxide film 5z is formed in a consistent film thickness within the range of 1 nm to 10 nm for example.

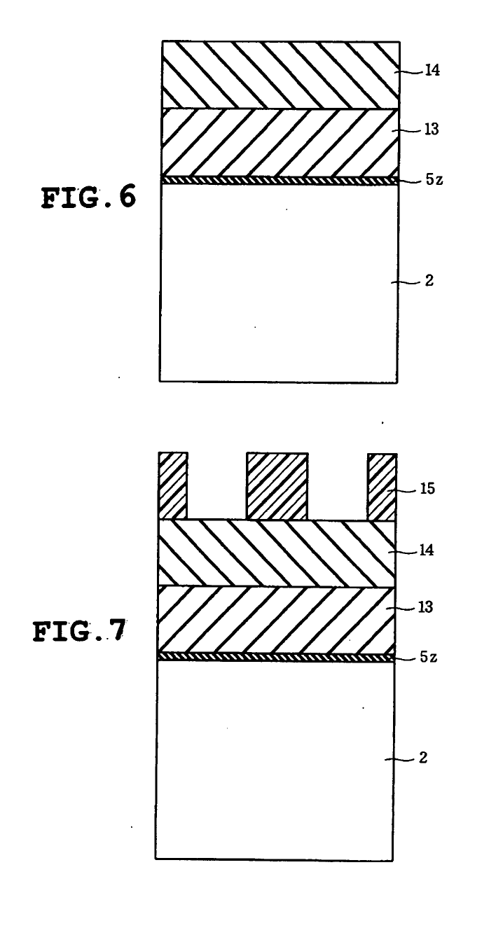

Then, referring to FIG. 5, the silicon nitride film 13 is formed on the silicon oxide film Sz by CVD (Chemical Vapor Deposition) process. The silicon nitride film 13 is formed in a consistent film thickness within the range of 50 nm to 200 nm for example. Next, referring to FIG. 6, the silicon oxide film 14 is formed on the silicon nitride film 13 by CVD process. The silicon oxide film 14 is formed in a consistent thickness within the range of 50 nm to 400 nm, for example.

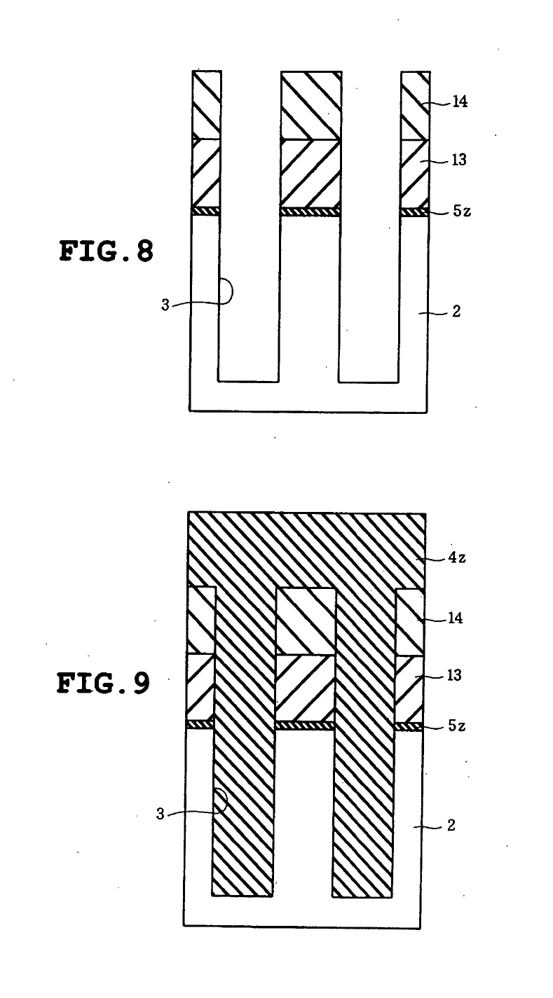

Then, referring to FIG. 7, a resist 15 is coated on the silicon oxide film 14 and patterned by photolithography process. Next, referring to FIG. 8, the silicon oxide film 14 is anisotropically etched along the Y-direction (direction intersecting the cross section illustrated in FIG. 7) by RIE (Reactive Ion Etching) process by using the patterned resist 15 as a mask, and the resist 15 is thereafter removed. Then, the silicon nitride film 13 is selectively and anisotropically etched by using the silicon oxide film 14 as a mask. Next, the element isolation trench 3 is defined on the surface layer of the silicon substrate 2 by etching the silicon oxide film 5z and the silicon substrate 2 by RIE process.

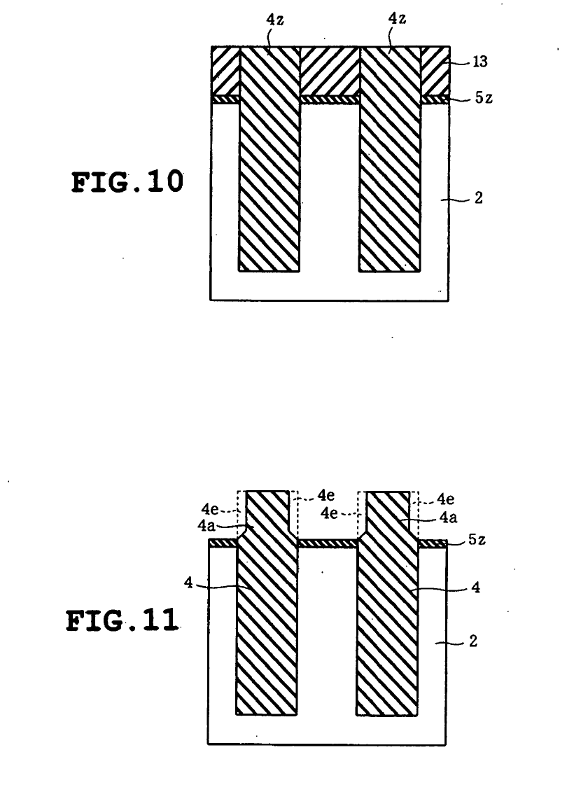

Next, referring to FIG. 9, the silicon oxide film 4z is filled inside the element isolation trench 3 to serve as the element isolation insulating film. Next, referring to FIG. 10, the silicon oxide film 4z is planarized by using the silicon nitride film 13 as a stopper. Next, referring to FIG. 11, the silicon nitride film 13 is selectively removed by wet-etch process using thermal phosphoric acid (H₃PO₄), or the like. At this time, since the wet-etch process proceeds isotropically, the X-directional (gate-width direction) width of the silicon oxide film 4z in the upper end proximity of the planarized silicon oxide film 4z can be formed narrower than the X-directional width of the silicon oxide film 4z in the proximity of the silicon oxide film 5z (proximity of the silicon substrate surface 2). In other words, upper angular portions (upper end portion) 4e of the silicon oxide film 4z can be removed isotropically to obtain the element isolation insulating film 4 having the protruding portion 4a on the upper portion thereof.

In such case, the upper angular portions 4e of the element isolation insulating film 4 can be removed without forming a mask pattern on the element isolation insulating film 4. The upper angular portion 4e may be removed by coating a resist (not shown) on the element isolation insulating film 4 or by using mask materials such as silicon nitride film (not shown). In such case, the upper angular portions 4e of the element isolation insulating film 4 may be removed not only by isotropic etch process such as wet-etch but also by anisotropic etch process such as RIE process.

Thus, the element isolation insulating film 4 can be filled inside the silicon substrate 2 while upwardly projecting the upper portion of the element isolation insulating film 4 from the surface of the silicon substrate 2 to divide the silicon substrate 2 surface into plurality of portions.

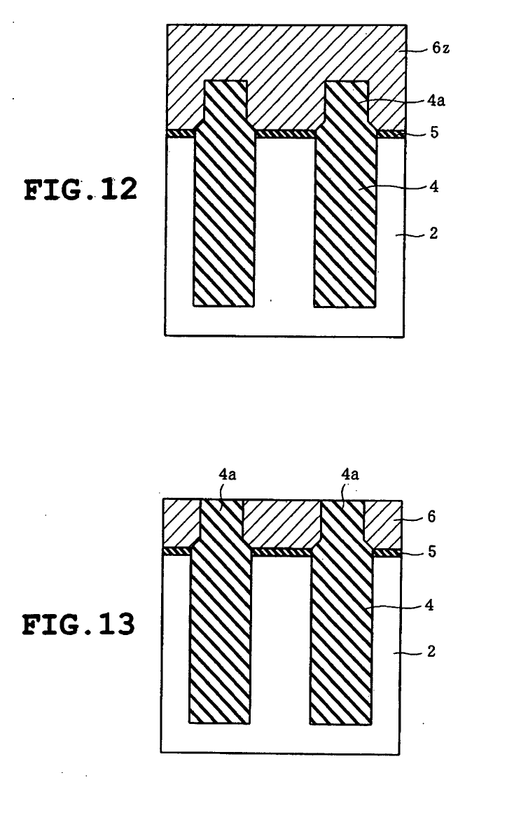

Next, referring to FIG. 12, the first gate insulating film 5 is formed on the silicon substrate 2 and the first polycrystalline silicon film 6z doped with impurities such as phosphorous is formed on the first gate insulating film 5 by CVD process in the thickness in the range of 10 nm to 200 nm, for example. Next, referring to FIG. 13, the first polycrystalline silicon film 6z is planarized by using the element isolation insulating film 4 as a stopper. The first conductive layer 6 is formed by the above described planarization process.

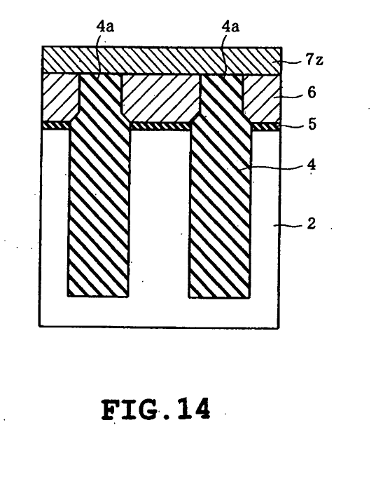

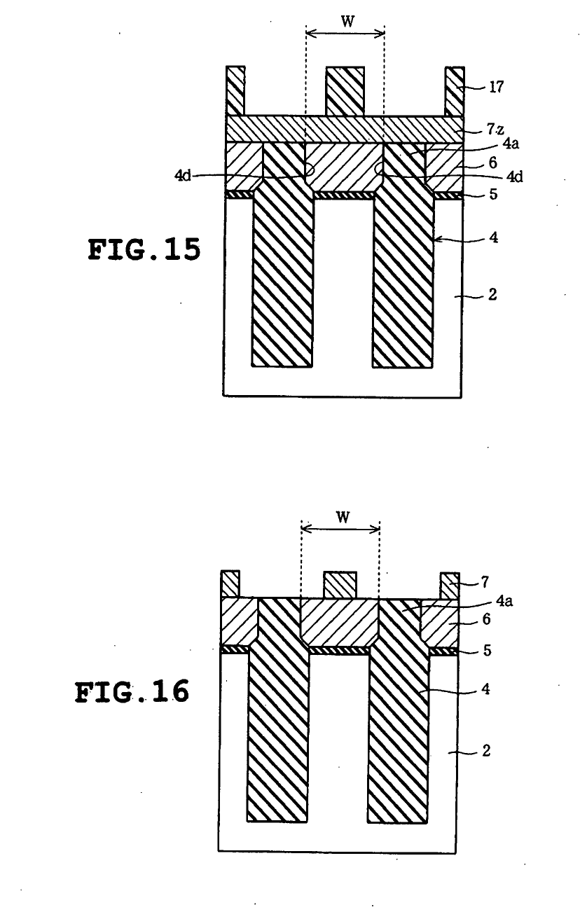

Next, referring to FIG. 14, the second polycrystalline silicon film 7z doped with impurities such as phosphorous is formed on the first conductive layer 6 and the element isolation insulating film 4 by CVD process in consistent thickness within the range of 10 nm to 200 nm. Next, referring to FIG. 15, a resist 17 is coated on the second polycrystalline silicon film 7z and the resist 17 is patterned by photolithography technique.

Next, referring to FIG. 16, the second polycrystalline silicon film 7z is removed by RIE process by using the patterned resist 17 as a mask. In such case, the second conductive layer 7 is configured on the central portion of the first conductive layer 6 by etching in a narrower dimension than the width of the patterned resist 17 by using a slimming technique for example. The X-directional width of the second conductive layer 7 is arranged to be different (narrower, for example) than a width W (refer to FIG. 15) between the sidewall surfaces 4d of the neighboring protruding portions 4a of the element isolation insulating film 4. The first and the second conductive layers 6 and 7 constitute the floating gate electrode FG.

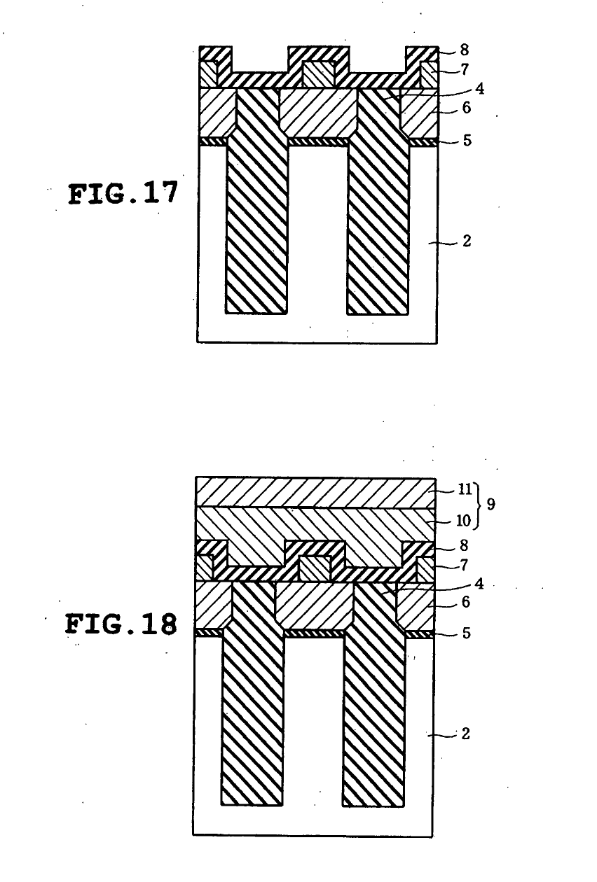

Next, referring to FIG. 17, the second gate insulating film 8 is formed so as to cover the element isolation insulating film 4, the first conductive layer 6, and the second conductive layer 7. An ONO film is formed as the second gate insulating film 8 by LPCVD process, for example. Next, referring to FIG. 18, the third polycrystalline silicon film (lower conductive layer) 10 and the low-resistive metal containing layer (upper conductive film) 11 constituted by tungsten silicide is formed on the second gate insulating film 8. The third polycrystalline silicon film 10 and the low-resistive metal film 11 constitute the third conductive layer 9 serving as the control gate electrode CG. Next, referring to FIG. 3, the silicon nitride film 12 is formed on the third conductive layer 9.

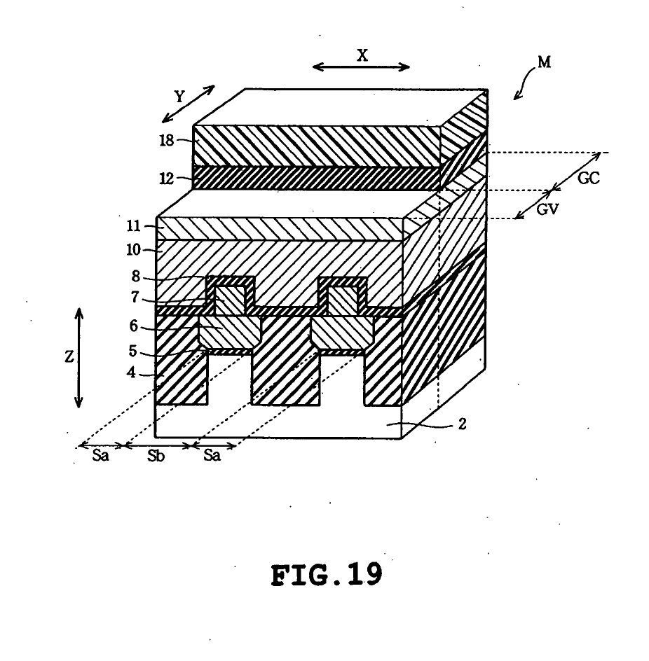

Next, the steps for separating the floating gate electrodes FG and control gate electrodes CG into plurality of portions in the Y-direction will be described with reference to FIGS. 19 to 23.

A resist 18 is coated on the silicon nitride film 12 and patterned thereafter. Referring to FIG. 19, the patterned region is a gate electrode forming region GC for forming the floating gate electrode FG and the control gate electrode CG and the resist 18 is patterned on the silicon nitride film 12 in the X-direction. The silicon nitride film 12 and/or the resist 18 is/are formed as a gate processing pattern.

Also, the silicon nitride film 12 is removed by etch process by using the patterned resist 18 as a mask, and the silicon nitride film 12 in the gate electrode isolation region GV is removed so as to retain the silicon nitride film 12 in the gate electrode forming region GC.

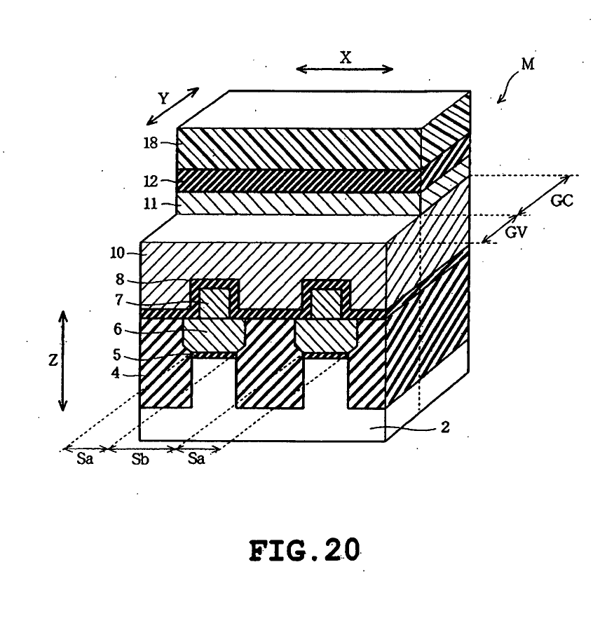

Next, referring to FIG. 20, the upper conductive layer 11 is etched by using the patterned resist 18 as a mask to remove the upper conductive layer 11 formed on the gate electrode isolation region GV. Hence, the upper layer conductive layer 11 remains on the gate electrode forming region GC. The present embodiment describes etch process being carried out by using the patterned resist 18 as a mask; however, the resist 18 may be removed and the upper conductive layer 11 may thereafter be removed by using the silicon nitride film 12 as a mask.

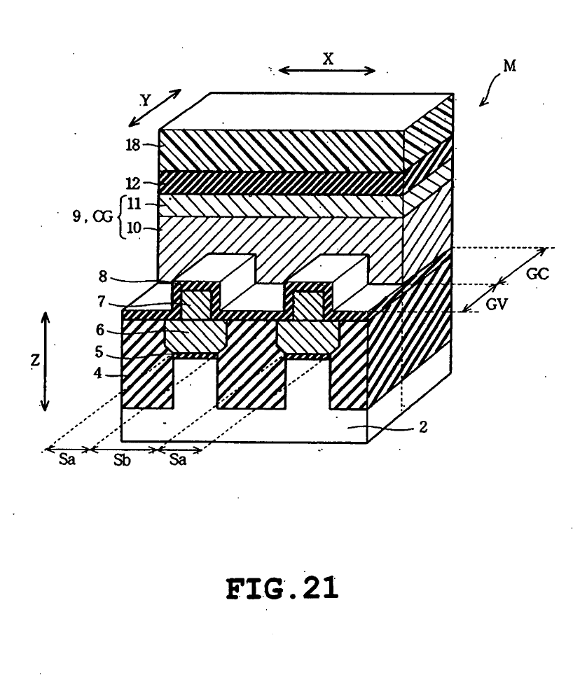

At this time, as illustrated in FIG. 21, when removing the upper conductive layer 11, the lower conductive layer 10 is removed simultaneously. This etch process removes the lower conductive layer 10 formed in the gate electrode isolation region GV, consequently allowing the third conductive layer 9 (control gate electrode CG) to remain in the gate electrode forming region GC. Thus, the control gate electrode CG (upper conductive layer 11 and the lower conductive layer 10) can be structurally separated in the Y-direction (direction intersecting the X-direction within the upper surface of the silicon substrate 2).

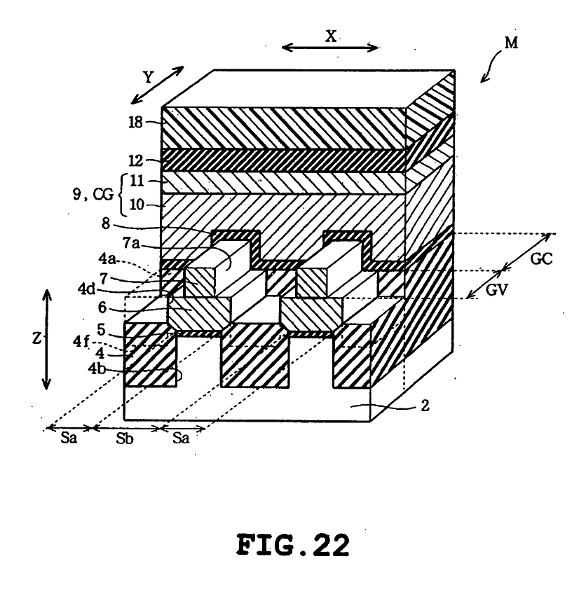

Next, referring to FIG. 22, the second gate insulating film 8 formed in the gate electrode isolation region GV is removed by anisotropically etching (RIE, for example) the second gate insulating film 8 by using the resist 18 as a mask. In such case, in order to remove the second gate insulating film 8 formed along the sidewall surface 7a of the second conductive layer 7, the second gate insulating film 8 needs to be etched for a long time. Moreover, since the second gate insulating film 8 serving as an insulating film needs to be etched for a long time under high-selectivity relative to polycrystalline silicon, the second gate insulating film 8 and the element isolation insulating film 4 formed immediately under the second gate insulating film 8 is removed at the same time.

In the present embodiment, as illustrated in FIG. 22, the upper portion of the element isolation insulating film 4 is formed as a tapered protruding portion 4a at a portion above the upper surface of the silicon substrate 2, and the lower end of the first conductive layer 6 in alignment with the surface 4d of the element isolation insulating film 4 does not contact the silicon substrate 2 or the silicon oxide film 5 (first gate insulating film). Thus, even if prolonged etch time is required when removing the second gate insulating film 8 formed on the sidewall surface 7a of the second conductive layer 7, the etch process does not affect the silicon substrate 2.

This is because, the first conductive layer 6 is formed on the silicon oxide film 5 so as to project outwardly relative to the sidewall surface 4b (sidewall surface inside the silicon substrate 2) of the element isolation insulating film 4, thus, only the upper portion (refer to FIG. 22) of the substantial central portion of the plane of the element isolation insulating film 4 is removed even if prolonged anisotropic etch is carried out. Moreover, even if further prolonged etch is carried out, since the etch proceeds vertically downward from the upper portion of the element insulating film 4, only a region 4f in the inner side of the element isolation insulating film 4 is removed. Thus, the removing process does not affect the interface between the silicon substrate 2 and the sidewall surface 4b.

Thus, since the sidewall 7a of the second conductive layer 7 is formed so as not to be in alignment with the sidewall surface 4d of the protruding portion 4a of the element isolation insulating film 4 and the upper portion of the element isolation insulating film 4 is formed as a tapered protruding portion 4a; there is no need for meticulous adjustment of etch time especially when removing the second gate insulating film 8. Moreover, even if prolonged etch is carried out, there will be no concerns of etching into the silicon substrate 2 and the etch end point need not be detected.

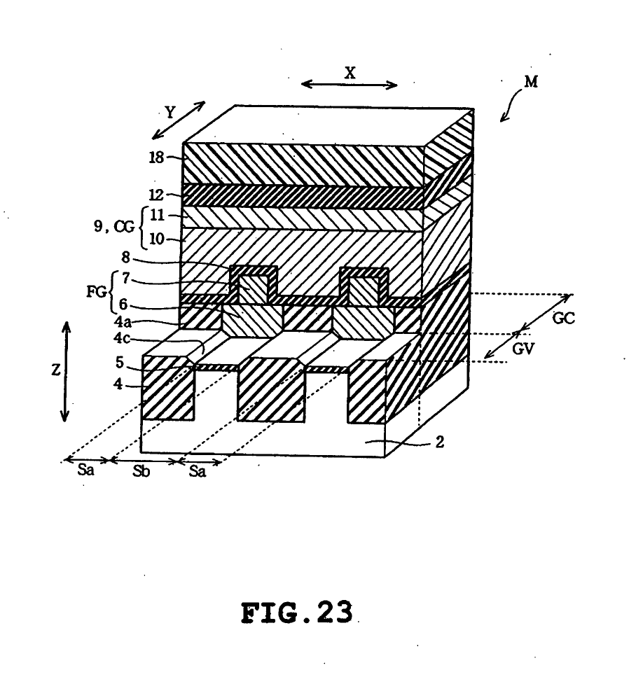

Next, referring to FIG. 23, the first and the second conductive layers 6 and 7 of the gate electrode isolation region GV are removed by anisotropic etch (RIE, for example). In this case, as illustrated in FIG. 23, since the upper portion of the element isolation insulating film 4 is sloped upwardly to define a tapered form especially in the portion above the silicon substrate 2 upper surface, the first and the second conductive layers 6 and 7 formed along the upper outer surface 4c of the element isolation insulating film 4 can be removed with less difficulty. Thus, the first and the second conductive films 6 and 7 are less prone to remain on the upper outer surface 4c of the element isolation insulating film 4, thereby allowing prevention of shorting defects between the neighboring floating gate electrodes FG in the Y-direction.

Thereafter, reaction product (not shown) generated from the etch process is removed by wet-etch and the source/drain diffusion layers (not shown) are formed. Detailed descriptions on the steps following thereafter will be omitted since they are generally known steps in configuring the NAND flash memory device 1 such as formation of spacer films (not shown), interlayer insulating films(not shown) and bit lines BL.

As described above, according to the manufacturing steps of the present embodiment, the sidewall 7a of the second conductive layer 7 is formed so as not to be in alignment with the sidewall surface 4d of the element isolation insulating film 4 when viewed in the X-directional cross section, and the upper portion of the element isolation insulating film 4 is formed as a tapered protruding portion 4a. Thus, the effect of removing the respective layers 6 to 12 of the gate electrode isolation region GV will not affect the silicon substrate 2 even if time taken in removing especially the second gate insulating film 8 is prolonged.

Moreover, when the first conductive layer 6 of the gate electrode isolation region GV is removed, since the upper outer surface 4c of the element isolating insulating film 4 on which the first conductive layer 6 is formed is sloped, the first conductive layer 6 on the gate electrode isolation region GV can be readily removed, thereby preventing shorting of a plurality of neighboring floating gate electrodes FG in the Y-direction (intersecting direction) intersecting the X-direction (gate-width direction) and improving device reliability.

The present disclosure is not limited to the above embodiments but may be modified or expanded as follows.

The present disclosure has been applied to a flash memory device 1; however it may be applied to other semiconductor devices.

The silicon substrate 2 is applied as a semiconductor substrate; however, a semiconductor substrate composed of other materials may be applied instead.

The present disclosure has been applied to the stacked gate electrode structure constituted by floating gate electrodes FG and control gate electrodes CG; however, other stacked gate structures may be employed instead.

The silicon oxide film 5 has been applied as the first gate insulating film; however, gate insulating films composed of other materials may be applied instead.

The ONO film has been applied to the second gate insulating film 8; however, a single layered film composed of either of a silicon nitride film, aluminum oxide film, hafunium oxide, zirconium oxide; or a laminated film composed of a plurality of these films; or a combination of a silicon oxide film and at least one of these films may be applied as the second gate insulating film 8. Such arrangement provides more suitable film material for inter-conductive layer insulating film between the floating gate electrode FG and the control gate electrode CG.

The above described embodiment describes the first conductive layer 6 being provided with an expanding portion 6b which expands upward and in the X-direction from the contacting portion 6a, and a protruding portion 4a of the element isolation insulating films 4 being configured in a single-peaked form, lumped form, trapezoid form, tapered form, or a curved form in which the outer surface thereof is curved downward. However, instead of the above configuration, as illustrated in the drawings (FIG. 3 in particular), an upper side surface of the expanding portion 6b of the first conductive layer 6 may be formed in a vertical form whereas a lower side surface thereof may be configured as an inclined portion being continuous with the upper side surface and with the upper surface 5a (the contacting portion 6a of the first conductive layer 6) of the silicon oxide film 5. The upper side surface of the protruding portion 4a of the element isolation insulating films 4 may be formed as a vertical portion (in a vertical form).

The elements described in the above embodiments may be omitted as long as the objective of the present disclosure can be achieved.

The foregoing description and drawings are merely illustrative of the principles of the present disclosure and are not to be construed in a limited sense. Various changes and modifications will become apparent to those of ordinary skill in the art. All such changes and modifications are seen to fall within the scope of the disclosure as defined by the appended claims.

What is claimed is:

1. A semiconductor device, comprising:
a semiconductor substrate;
a plurality of element isolation insulating films delimiting the semiconductor substrate into a plurality of element forming regions, each element isolation insulating film formed so as to fill a trench defined in the semiconductor substrate and having an upper end that upwardly projects from a surface of the semiconductor substrate, and a width of the upper end being formed narrower than a width at a height of a surface portion of the semiconductor substrate;
a first gate electrode formed on the element forming region via a first gate insulating film, the first gate electrode having a lower electrode having an upper surface portion at level with a height of the upper end of the element isolation insulating film and having a sidewall surface in alignment with a sidewall surface of the element isolation insulating film projecting from the surface of the semiconductor substrate, the lower electrode being formed between the plurality of element isolation insulating films; and having an upper electrode formed on the upper surface portion of the lower electrode and having a width narrower than a width of the lower electrode, the upper electrode having a sidewall surface which is not in alignment with the sidewall surface of the element isolation insulating film;
a second gate insulating film formed so as to cover the upper surface of the lower electrode of the first gate electrode, an upper surface of the element isolation insulating film, and a surface of the upper electrode of the first gate electrode;
and a second gate electrode formed on the second gate insulating film.

2. The device of claim 1, wherein the element isolation insulating film is provided with a tapered portion sloped relative to the upper surface of the semiconductor substrate in the surface portion of the semiconductor substrate.

3. The device of claim 1, wherein the first and the second gate electrodes include a polycrystalline silicon film.

4. The device of claim 3, wherein the second gate insulating film includes a pair of silicon oxide films and a silicon nitride film located between the silicon oxide films.

5. The device of claim 1, wherein each element isolation insulating film includes a silicon oxide film, respectively.

6. A semiconductor device, comprising:
a semiconductor substrate including a first upper surface having an element forming region and an element isolation region, the element isolation region having a trench;
an element isolation insulating film embedded in the trench, the element isolation insulating film including a protruding portion protruding from the first upper surface of the semiconductor substrate and a surface level portion located at an upper end portion of the trench, the protruding portion including a first side surface and a second upper surface having a first width, the surface level portion including a second width being longer than the first width;
a floating gate electrode having an underside formed on the semiconductor substrate in the element forming region via a first gate insulating film, the floating gate electrode including a lower portion and an upper portion formed on the lower portion, the lower portion including a third upper surface being flush with the second upper surface of the element isolation insulating film and a second side surface contacting with the first side surface of the element isolation insulating film, the third upper surface including a third width, the upper portion including a third side surface and a fourth upper surface having a fourth width being shorter than the third width of the third upper surface;
a second gate insulating film formed on the second, the third and the fourth upper surfaces and the third side surface; and
a control gate electrode formed on the second gate insulating film.

7. The device of claim 6, wherein a first corner portion which is defined by the third side surface and the third upper surface is separated from a second corner portion which is defined by the second side surface and the third upper surface by a predetermined distance.

8. The device of claim 6, wherein the second side surface of the floating gate electrode includes an inclined portion which is continuous with the underside of the floating gate electrode and a vertical portion located on the inclined portion and which is continuous with the third upper surface of the floating gate electrode.

9. The device of claim 6, wherein the floating and the control gate electrodes include a polycrystalline silicon film.

10. The device of claim 9, wherein the second gate insulating film includes a pair of silicon oxide films and a silicon nitride film located between the silicon oxide films.

11. The device of claim 6, wherein the element isolation insulating film includes a silicon oxide film.

12. A method of manufacturing a semiconductor device, comprising:
forming a first insulating film on a semiconductor substrate;
forming a plurality of element isolation insulating films separating a surface of the semiconductor substrate in a predetermined gate-width direction while projecting an upper end thereof upward relative to an upper surface of the first insulating film;
processing each of the element isolation insulating film so that a width in the predetermined gate-width direction of the upper end of the element isolation insulating film is narrower than a width in the predetermined gate-width direction of the element isolation insulating film at a height of a surface portion of the semiconductor substrate;
forming a first conductive film on a first gate insulating film formed on the surface of the semiconductor substrate so as to fill gaps between the plurality of element isolation insulating films;
forming a second conductive film on the first conductive film so that a sidewall surface in the gate width direction is not in alignment with a sidewall surface of the element isolation insulating film in an upper side of the semiconductor substrate;
forming the second gate insulating film so as to cover the second conductive film;
forming a third conductive film on the second gate insulating film; and
separating the third conductive film, the second gate insulating film, the second conductive film, and the first conductive film into a plurality of portions in a direction intersecting the gate-width direction by removing the third conductive film, the second gate insulating film, the second conductive film and the first conductive film along the predetermined gate-width direction within the surface of the semiconductor substrate.

13. The method of claim 12, wherein the first, second and third conductive film includes a polycrystalline silicon film.

14. The method of claim 12, wherein each element isolation insulating film includes a silicon oxide film, respectively.

15. The method of claim 12, wherein the separating step is executed by a reactive ion etching method.

16. A method of manufacturing a semiconductor device, comprising:
forming a first silicon oxide film on a semiconductor substrate;
forming a silicon nitride film on the first silicon oxide film;
forming a second silicon oxide film on the silicon nitride film;
coating a first resist on the second silicon oxide film, and patterning the first resist into a predetermined pattern;
etching the second silicon oxide film by using the patterned first resist as a mask, and etching the silicon nitride film, the first silicon oxide film, and the semiconductor substrate by using the etched second silicon oxide film as a mask, and forming a plurality of trenches in a first direction;
filling the trench with a third silicon oxide film;
planarizing the second silicon oxide film and the third silicon oxide film by using the silicon nitride film as a stopper;
arranging a width of an upper end of the third silicon oxide film projecting from a surface of the semiconductor substrate to be narrower than a width of the third silicon oxide film at a height of a surface portion of the semiconductor substrate by removing the silicon nitride film exposed by planarization by wet-etch process and removing a portion of a side surface of the third silicon oxide film projecting from the surface of the semiconductor substrate;
forming a first gate insulating film on the semiconductor substrate in a portion between a plurality of the third silicon oxide films projecting from the surface of the semiconductor substrate;
filling a region delimited by the plurality of the third silicon oxide films projecting from the surface of the semiconductor substrate and overlying the first gate insulating film with a first conductive film,
planarizing the first conductive film by using the third silicon oxide film as a stopper;
forming a second conductive film on the planarized first conductive film;
coating a resist on the second conductive film and patterning the resist by photolithography process, etching the second conductive film by using the patterned resist as a mask, and forming the second conductive film having a width of the sidewall surface narrower than the width of the first conductive film on the first conductive film;
forming a second gate insulating film on the first conductive film, the second conductive film, and the third silicon oxide film;
forming a third conductive film on the second gate insulating film; and
removing the third conductive film, the second gate insulating film, the second conductive film and the first conductive film in a direction intersecting the first direction and separating the third conductive film, the second gate insulating film, the second conductive film, and the first conductive film in the first direction.

17. The method of claim 16, wherein the first, second and third conductive film include a polycrystalline silicon film.

18. The method of claim 16, wherein the removing step is executed by a reactive ion etching method.
